(19) United States
(12) Patent Application Publication
(10) Pub. No.: US 2024/0290884 A1
(43) Pub. Date: Aug. 29, 2024

(54) STRESS INCORPORATION IN SEMICONDUCTOR DEVICES

(71) Applicant: Applied Materials, Inc., Santa Clara, CA (US)

(72) Inventors: El Mehdi Bazizi, San Jose, CA (US); Sai Hooi Yeong, Cupertino, CA (US); Benjamin Colombeau, San Jose, CA (US); Balasubramanian Pranatharthiharan, San Jose, CA (US); Hui Zhao, Saratoga, CA (US); Ashish Pal, San Ramon, CA (US)

(73) Assignee: Applied Materials, Inc., Santa Clara, CA (US)

(21) Appl. No.: 18/441,824

(22) Filed: Feb. 14, 2024

Related U.S. Application Data
(60) Provisional application No. 63/487,501, filed on Feb. 28, 2023.

(51) Int. Cl. H01L 29/78; H01L 21/762; H01L 29/06; H01L 29/423; H01L 29/66; H01L 29/775; H01L 29/786

(52) U.S. Cl. CPC H01L 29/7846; H01L 21/76224; H01L 29/0649; H01L 29/42392; H01L 29/66439; H01L 29/775; H01L 29/78696

(57) ABSTRACT

The present technology includes semiconductor devices with improved stress in a channel region. The semiconductor devices include a substrate, a source region, a drain region, a channel region that includes at least one channel located between the source and the drain, a first gate region, and a second gate region. The first gate region includes a self-aligned single diffusion break, and the second gate region includes a first gate enclosing the channel between the source region and the drain region. The self-aligned single diffusion break also contains a stressed dielectric material having a stress of about 500 MPa or greater.

### CROSS-REFERENCE TO RELATED APPLICATION

This application claims the benefit of U.S. Provisional No. 63/487,501 filed on Feb. 28, 2023, entitled “STRESS INCORPORATION IN SEMICONDUCTOR DEVICES,” the entire contents of which are incorporated herein by reference.

### TECHNICAL FIELD

The present technology relates to methods for semiconductor processing. More specifically, the present technology relates to methods for incorporating increased stress in doped regions of semiconductor devices.

### BACKGROUND

Integrated circuits have advanced into complex devices that can include millions of transistors, capacitors, and resistors on a single chip. In the course of integrated circuit evolution, functional density (i.e., the number of interconnected devices per chip area) has generally increased while geometry size has decreased. Transistors are circuit components or elements that are often formed on semiconductor devices. Many transistors may be formed on a semiconductor device in addition to capacitors, inductors, resistors, diodes, conductive lines, or other elements, depending on the circuit design. Integrated circuits incorporate field-effect transistors (FETs) in which current flows through a semiconducting channel between a source and a drain, in response to a voltage applied to a control gate.

Integrated circuits are made possible by processes which produce intricately patterned material layers on substrate surfaces. Producing patterned material on a substrate requires controlled methods for forming and removing material. As device sizes continue to reduce, film characteristics may lead to larger impacts on device performance. As devices shrink and more complex patterning schemes are utilized in the industry, deposition of thin films becomes a challenge. In addition, as material thicknesses continue to reduce, as-deposited characteristics of the films may have a greater impact on device performance. These challenges include depositing void free and stressed films.

Thus, there is a need for high-quality devices and structures having improved mobility, and methods of making such devices. These and other needs are addressed by the present technology.

### BRIEF SUMMARY OF THE INVENTION

Embodiments of the present technology include semiconductor devices with improved stress in a channel region. Embodiments of the semiconductor device include a substrate, a source region, a drain region, a channel region that includes at least one channel located between the source and the drain, a first gate region, and a second gate region. The first gate region includes a self-aligned single diffusion break in a p-MOS region, and the second gate region includes a first gate enclosing the channel between the source region and the drain region. The self-aligned single diffusion break also contains a stressed dielectric material having a compressive stress of greater than or about 500 MPa.

In embodiments, the channel region has a compressive stress of greater than or about 500 MPa. In further embodiments, the semiconductor device also includes a third gate region, where the second gate region is disposed between the first gate region and the third gate region. In more embodiments, the third gate region includes a second self-aligned single diffusion break. Additional embodiments include a channel region having a first channel region stress at a first location and a second channel region stress at a second location spaced apart from the first location within the channel region, where the first channel region stress varies from the second channel region stress by about 30% or less. Embodiments include where the channel region contains a plurality of horizontally extending channels. In embodiments, the semiconductor device is a nanosheet field-effect transistor or a complementary field-effect transistor. In further embodiments, the semiconductor device is a gate-all-around complementary metal-oxide semiconductor.

Embodiments include a second gate region having a tensile stressed dielectric material or a high-energy implantation having a tensile stress of greater than or about 500 MPa. In additional embodiments, the third gate region contains a compressive stressed dielectric material having a compressive stress of greater than or about 500 MPa. In further embodiments, the third gate region contains a compressive stressed dielectric material. In more embodiments, the self-aligned diffusion break defines a volume, where the stressed dielectric material occupies greater than or about 90 vol. % of the volume. In embodiments, the stressed dielectric material is generally free of voids or seams. Embodiments include where the stressed dielectric material occupies greater than or about 98 vol. % of the self-aligned diffusion break volume. In additional embodiments, the stressed dielectric material has a compressive stress of greater than or about 1000 MPa, the channel region is a p-channel metal oxide semiconductor, and the channel region has a compressive stress of greater than or about 600 MPa.

Embodiments of the present technology also include a semiconductor processing system. The semiconductor processing system includes a first processing chamber; a second processing chamber; a third processing chamber; and a system controller. In embodiments, the system controller is configured to pattern a substrate in the first processing chamber, etch a shallow trench isolation in a first gate region of a semiconductor device, where the first gate region is a p-MOS region, in a second processing chamber, and fill the shallow trench isolation with a stressed dielectric material having a compressive stress of at least about 500 MPa in a third processing chamber.

Embodiments of the present technology also include a method of forming a semiconductor device with improved stress in a channel region. The method includes etching a shallow trench isolation in a first gate region of a semiconductor device. The semiconductor device includes a substrate, a source region, a drain region, a channel region containing at least one channel located between the source and the drain, a first gate region, and a second gate region. The second gate region includes a first gate enclosing the channel between the source region and the drain region. The method includes filling the shallow trench isolation with a stressed dielectric material having a stress of at least about 500 MPa.

In embodiments, the semiconductor device exhibits a first stress amount in the channel region prior to etching and filling, and a second stress amount in the channel region after etching and filling, wherein a percentage change from the first stress amount to the second stress amount is greater than or about 10% or the semiconductor device exhibits a first hole mobility prior to etching and filling, and a second hole mobility after etching and filling, wherein a percentage change from the first hole mobility to the second hole mobility is greater than or about 10%. In further embodiments, the semiconductor device includes a third gate region, the second gate region being disposed between the first gate region and the third gate region. Embodiments include where the third gate region is etched during the etching of the first gate region, or where the third gate region is masked during the etching of the first gate region and undergoes patterning and etching after the first gate region has been etched, forming a second shallow trench isolation in the third gate region. In yet further embodiments, the shallow trench isolation is filled with a compressive stressed dielectric material, and the second shallow trench isolation is filled with a compressive stressed dielectric material, a tensile stressed dielectric material, or a high energy implantation.

Such technology may provide numerous benefits over conventional techniques. For example, embodiments of the present technology produce desired levels of stress in the channel region of a semiconductor transistor without changing the composition of the adjacent source and drain regions. In addition, the present technology originates the channel region stress from an existing diffusion break, thus allowing more compact devices to be formed with improved stress. The present technology may therefore provide for improved stress without requiring additional channels or diffusion breaks having increased size. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing chamber according to some embodiments of the present technology.

FIG. 2 shows selected operations in a formation method according to some embodiments of the present technology.

FIGS. 3A-3E show cross-sectional views of exemplary semiconductor structures according to some embodiments of the present technology.

FIG. 4 shows a cross-sectional view of exemplary semiconductor structures according to some embodiments of the present technology.

FIG. 5 shows selected operations in a formation method according to some embodiments of the present technology.

FIG. 6 shows selected operations in a formation method according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

The present technology includes electronic devices and methods of forming electronic devices having one or more self-aligned single diffusion breaks. Such electronic devices may include a semiconductor transistor, such as n-channel and p-channel MOSFETs, FinFETs, gate-all-around FETs, and nanosheet FETs, among other types of transistors, as well as products having such channel regions. In conventional technologies, the stress level in the transistor channel may be controlled by altering the composition of the semiconductor materials in the channel, as well as the compositions of the materials in the adjacent source and drain regions. In many instances, the changes to the compositions of these doped regions of the transistor to give the channel region a desired amount of stress can lead to less desirable transistor performance in other respects, such as a lower thermal budget and/or an increased resistance at the interface between the contact and the doped region. Controlling channel region stress by altering the composition of the doped regions also limits the types of materials that can be used in the doped regions. For example, modern PMOS transistors often use a doped silicon-germanium (SiGe) semiconductor in the doped regions of the transistor. When the Ge-to-Si ratio gets too high, lattice mismatches create faults in the material that can reduce the channel region stress below an acceptable level.

Another conventional method for increasing the stress in a channel region of a transistor is depositing a stressed conductive material in the contact trench above the channel region. The stress from the conductive material is transmitted down to impart the required stress in the doped material of the channel region. These conventional methods also require careful selection and deposition of the conductive material in the contact trench to meet the stress requirements as well as the electrical conductivity, chemical reactivity, hermeticity, thermal budget, and other requirements for the material. In many instances, there must be a compromise in selecting a conductive material with less-than-ideal characteristics in some respects in order to satisfy the stress requirement. The changes in the deposition method or composition of the stressed material to create additional stress diminishes the performance of the material in other respects, such as electrical conductivity.

Nonetheless, conventional methods have proven increasingly ineffective with the rise of increasingly complicated gate and channel surface orientations. Namely, the gate orientation of multi-channel semiconducting nanostructures, such as gate-all-around, complementary FET, nanosheet, and nanowire orientations, as examples only, hinder the effectiveness of conventional stress applications. As one example, conventional methods for increasing stress may apply adequate stress at an upper and/or lower gate but fails to provide the necessary stress on gates disposed therebetween. Furthermore, due at least in part to poor stress consistency in addition to unfavorable surface orientations, multi-channel semiconducting nanostructures also exhibit unfavorable hole and/or electron mobility. Such hole mobility deficiencies are particularly apparent in comparison to traditional gate and favored channel orientations, such as fin field-effect transistors (FinFET).

Efforts to improve channel strain in multi-channel semiconducting nanostructures in particular include source and drain regions formed via an epitaxial growth process. However, due to the complex geometries and surface orientations, particularly in p-type metal oxide semiconductor (PMOS) regions, epitaxial merging consistently suffers from dislocations during and after formation. Such dislocations can pull the epitaxially grown material away from the gates, as well as create dislocation seams, leading to a relaxation in the channel stress over time. Methods have sought to improve epitaxial merge defects as a method to impart consistent channel stress. However, none of the existing methods have proven sufficient to provide consistent stress and/or improve electron and hole mobility.

The present technology overcomes these challenges by providing consistently stressed channels having improved hole and/or electron mobility. By utilizing one or more self-aligned single diffusion breaks having a dielectric stressor film, stressed channel regions may be provided, without having to alter the compositions of the doped regions of the transistor. In embodiments of the present technology, the stresses originate with the deposition of a stressed material in one or more self-aligned single diffusion breaks that are adjacent to one or more doped regions of the transistor. The stressed material may initially impart stress to the one or more self-aligned single diffusion breaks, which in turn may transmit a portion of the stress to the channel region of the transistor.

Although the remaining disclosure will routinely identify specific metal-oxide-semiconductor field-effect transistors (MOSFET), complementary metal-oxide semiconductors (CMOS), and components thereof, it will be readily understood that the device and methods are equally applicable to other field-effect transistors, orientations thereof, as processes for forming such devices. Accordingly, the technology should not be considered to be so limited as for use with these specific devices or methods alone. The disclosure will discuss one possible semiconductor device that may include one or more components, utilizing one or more self-aligned single diffusion breaks according to embodiments of the present technology before additional variations and adjustments to this apparatus according to embodiments of the present technology are described.

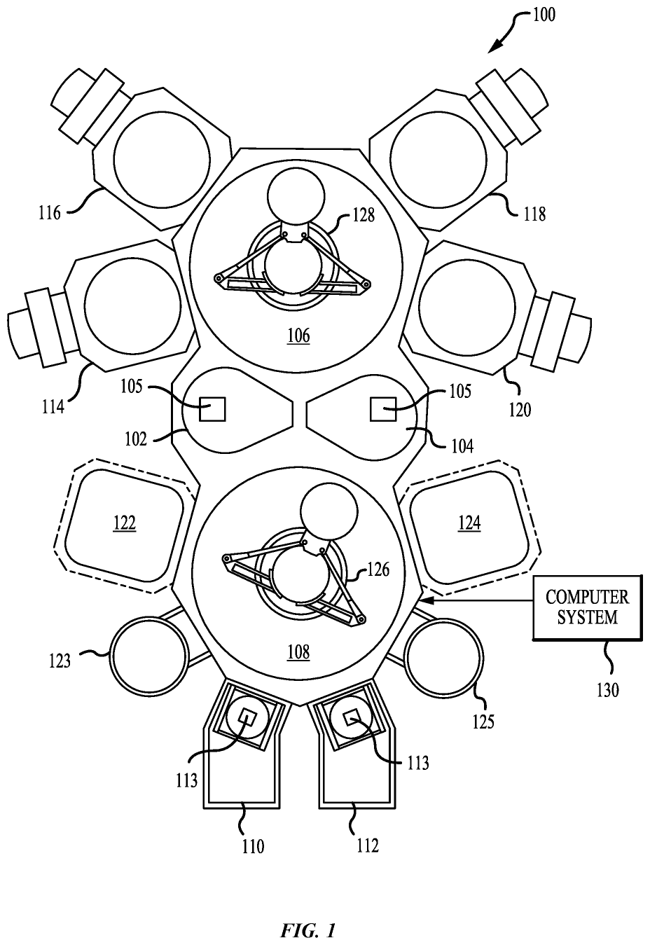

FIG. 1 illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

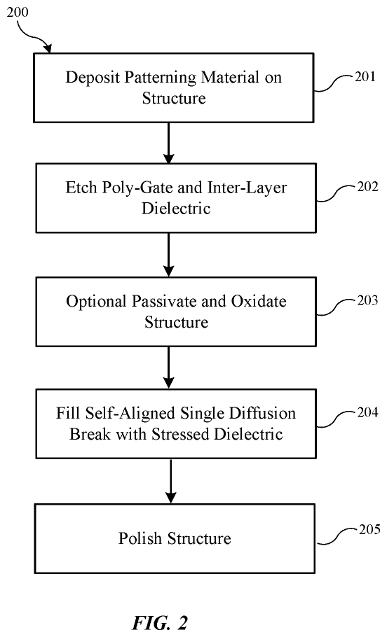

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

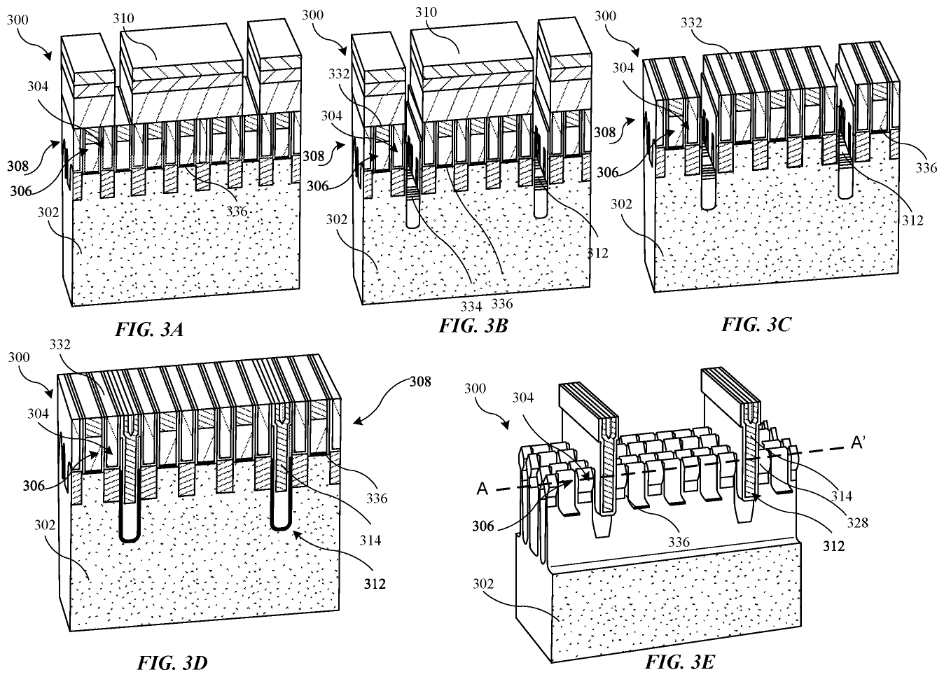

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing region 120 described above. Method 200 describes operations shown schematically in FIGS. 3A-3E, the illustrations of which will be described in conjunction with the operations of method 200. It is to be understood that FIGS. 3A-3E illustrate only partial schematic views, and a semiconductor substrate may include further components as illustrated in the figures, as well as alternative components, of any size or configuration that may still benefit from aspects of the present technology.

Method 200 may or may not involve optional operations to develop the semiconductor structure to a particular fabrication operation. It is to be understood that method 200 may be performed on any number of semiconductor structures 300 or substrates 302, as illustrated in FIGS. 3A-3E, including exemplary structures on which a selective deposition material may be formed. As illustrated in FIG. 3A substrate 302 may have a number of layers of material deposited overlying the substrate. Substrate 302 may be any number of materials, such as a base wafer or substrate made of silicon or silicon-containing materials, germanium, other substrate materials, as well as one or more materials that may be formed overlying the substrate during semiconductor processing.

Structure 300 may illustrate a partial view of a substrate, which in embodiments may be used in n-channel and p-channel MOSFETs, FinFETs, gate-all-around FETs, complementary metal-oxide semiconductors, and nanosheet FETs, among other types of semiconductor transistor structures. The layers of material may be produced by any number of methods, including chemical vapor deposition (CVD), physical vapor deposition (PVD), atomic layer deposition (ALD), thermally enhanced chemical vapor deposition (TECVD), plasma-enhanced chemical vapor deposition (PECVD), plasma enhanced atomic layer deposition (PEALD), or any other formation technique. In embodiments, plasma-enhanced chemical vapor deposition may be performed in a processing chamber, such as processing chamber 100 described previously. Substrate layers can include silicon oxide and silicon nitride, silicon oxide and silicon, silicon nitride and silicon, silicon and doped silicon, or any number of other materials.

As illustrated in FIG. 3A, structure 300 is provided that includes a substrate 302 that has already undergone source/drain 304 formation. In embodiments, source/drain 304 formation may include epitaxial growth of a doped silicon material such as a silicon-germanium material. Although, it should be understood that the source/drain region 304 may be formed from any suitable deposition and patterning process, as the present technology does not require stringent source/drain 304 formation (e.g., attempts to cure epitaxial growth defects) to maintain hole or electron mobility. In addition, structure 300 contains a plurality of gate regions 306 and interlayer dielectric/dummy gate region 308, which may be formed as known in the art and discussed above.

In embodiments, the substrate 300 may be a bulk semiconductor substrate. As used herein, the term “bulk semiconductor substrate” refers to a substrate in which the entirety of the substrate is comprised of a semiconductor material. The bulk semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 300 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. As discussed above, in embodiments, the present technology may provide improved mobility in both p and n-type semiconductors. However, in embodiments, p-type semiconductors may experience further improved hole mobility.

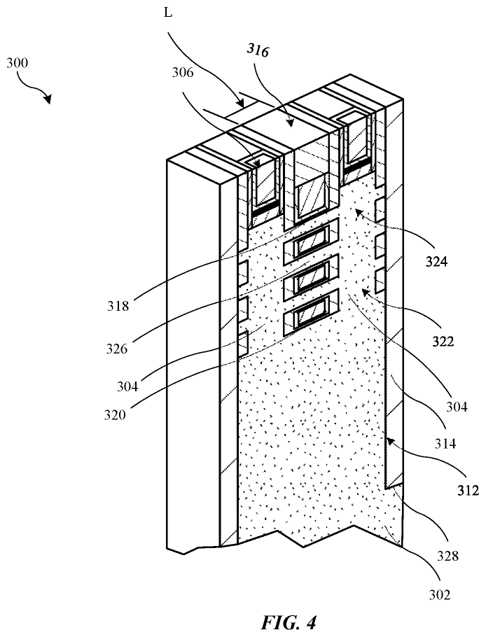

Nonetheless, at operation 201, method 200 may include patterning one or more mask layers 310 deposited on the substrate 302 on the upper surface of the source/drain regions 304 and a portion of gate regions 306. For instance, in embodiments, a substrate 302 may be loaded into load lock 110,112, and transferred to a process chamber (such as process chamber 114) via robots 106, 108, where a mask deposition process is conducted. Namely, as illustrated, one or more mask layers 310 are patterned above five of the seven illustrated gate regions 306, leaving two gate regions 306 exposed. However, as will be discussed in greater detail below, it should be understood that the patterned mask layers 310 may be disposed above one or more gates regions 306 or spaced apart at intervals as necessary to provide the necessary stress on channel regions 316 (shown more clearly in FIG. 4).

As illustrated in FIG. 3B, at operation 202, method 200 may include etching the structure 300. In embodiments, such an operation may include transferring substrate 302 to a second process chamber 116, configured for etching processes. For instance, in one embodiment, one or more of inductively coupled plasma (ICP) etching, reactive ion etching (RIE), or capacitively coupled plasma (CCP) etching is used to form shallow trench isolation or via 312. Furthermore, as the mask layers 310 are aligned with gate regions 306, the shallow trench isolations 312 may be formed in and self-aligned with a gate region, and thus considered to be self-aligned shallow trench isolations or self-aligned single diffusion breaks. Furthermore, as shown, in FIG. 3B, the self-aligned diffusion 312 break defines a volume from structure upper surface 332 to a bottom 334 of diffusion break 312.

After etching 202, the structure 300 may optionally undergo passivation and/or oxidation prior to operation 203, and removal of mask layers 310, as shown in FIG. 3C. Nonetheless, at operation 204, the etched substrate 302 may be transferred to a third process chamber 118 configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like, where the self-aligned diffusion break 312 is filled with stressed dielectric material 314.

Nonetheless, the etched and filled substrate 302 may be transferred to a fourth process chamber 120, such as a process chamber configured for polishing, including chemical mechanical polishing, and subjected to polishing operation 205, such as chemical mechanical polishing, of the top surface 332 of structure 300 (FIG. 3D). A further view of FIG. 3D is illustrated in FIG. 3E, where the interlayer dielectric 308 and gate regions 306 have been removed for clarity. In addition, FIG. 4 illustrates a cross-sectional view of an exemplary embodiment, such as along line A-A′ of FIG. 3E. FIG. 4 may more clearly show source/drain regions 304, gate regions 306, and channel regions 316. As illustrated, in embodiments, the structure 300 may be in a horizontal gate-all-around orientation, having a plurality of horizontally extending channels 326 in channel region 316. For instance, in embodiments, the channels 326 may be generally parallel with a top surface 336 of substrate 302. However, unlike conventional processes, the present technology proceeds with filling of the self-aligned diffusion break(s) with a stressed dielectric material 314 at operation 204.

Namely, the present technology has surprisingly found that by utilizing a stressed dielectric material 314 to fill self-aligned diffusion break(s) 312, excellent electron and/or hole mobility may be achieved, even in structures having disfavored channel surface orientation. Moreover, by utilizing a stressed dielectric material in the self-aligned diffusion break(s), the present technology has found that the compressive stress is transferred from the stressed material to the neighboring channel regions without suffering from channel stress relaxation exhibited in existing technologies.

For instance, the present technology has found that after filling, the stress in the one or more channel regions 316 (FIG. 3E, shown more clearly in FIG. 4) increases from a lower-stress, first stress amount to a higher-stress, second stress amount. In embodiments, the percentage change in the stress of a channel region 316 from the first stress amount to the second stress amount may be greater than or about 0.1%, such as greater than or about 1%, greater than or about 2%, greater than or about 5%, greater than or about 10%, greater than or about 25%, greater than or about 50%, greater than or about 75%, greater than or about 100%, or more, or any ranges or values therebetween. In additional embodiments, the first stress amount in a channel region 316 may be less than or about 10 MPa, less than or about 5 MPa, less than or about 1 MPa, or less. In further embodiments, the second stress amount in a channel region 316 may be greater than or about 100 MPa, such as greater than or about 200 MPa, such as greater than or about 300 MPa, such as greater than or about 400 MPa, such as greater than or about 500 MPa, such as greater than or about 600 MPa, such as greater than or about 700 MPa, such as greater than or about 750 MPa, or any ranges or values therebetween.

In addition, in embodiments, the present technology has found that such stress may be evenly distributed throughout the channel region 316. Namely, as noted above, previous attempts have utilized stressed materials above and below the channel regions. However, conventional technologies may limit stress improvement to a top side 318 of the channel region 316 and/or bottom side 320 of the channel region 316. Accordingly, conventional technologies may fail to provide consistent stress throughout the entirety of the channel. Conversely, in embodiments, the present technology may have a first channel stress at a first location 322 in channel region 316 (illustrated as adjacent to bottom 320 of channel region 316 for example only, it should be understood that first location 322 may be at any location within channel region 316), and a second channel stress at a second location 324 in channel region 316. As illustrated, the first location 322 is spaced apart from second location 424 in a vertical direction for exemplary purposes. However, in embodiments, the regions may be spaced apart horizontally, or both vertically and horizontally. Nonetheless, the first channel stress may vary from the second channel stress by less than or about 30%, such as less than or about 27.5%, less than or about 25%, less than or about 22.5%, less than or about 20%, less than or about 17.5%, less than about 15%, less than about 12.5%, less than or about 10%, or any ranges or values therebetween.

Furthermore, as noted above, the increased stress in the channel region may increase the mobility of charge carriers in the channel, which also may increase the drive current through the channel region. Specifically, the increased stress created in the channel region in embodiments of the present technology may increase the drive current, such as the p-MOS drive current in embodiments, through a transistor channel by greater than or about 1%, such as greater than or about 5%, greater than or about 10%, greater than or about 15%, greater than or about 20%, greater than or about 25%, greater than or about 30%, greater than or about 35%, greater than or about 40%, greater than or about 45%, greater than or about 50%, greater than or about 55%, or any ranges or values therebetween. In embodiments, the increased stress in the channel region may lead to an even further increase in the hole mobility, such as in an amount of greater than or about 10%, greater than or about 20%, greater than or about 30%, greater than or about 40%, greater than or about 50%, greater than or about 60%, greater than or about 70%, greater than or about 80%, greater than or about 90%, greater than or about 100%, greater than or about 110%, greater than or about 120%, greater than or about 130%, greater than or about 140%, greater than or about 150%, or any ranges or values therebetween. An increase in drive current and hole mobility through the channel region can increase transistor performance in a number of respects including, but not limited to, increased switching speed and/or reduced power consumption. Embodiments of the present technology may accomplish these improvements in semiconductor device performance without constraining the types of materials used in the devices that may create new processing problems or compromise device performance in other respects.

Nonetheless, in embodiments, the amount of stress in the stressed dielectric material may depend on the amount of stress that should be imparted to the channel region of the semiconductor device as a result of depositing the stressed material. In embodiments, this may involve a determination of the amount of stress desired in the one or more channel regions 316. Exemplary stressed materials may include a dielectric material such as a silicon oxide, silicon nitride, silicon oxynitride, silicon oxycarbonitride, silicon carbonitride, silicon oxycarbide, silicon dioxide, aluminum oxide, and carbon-containing organic materials, among other types of dielectric materials, and combinations thereof. The present technology permits a selection of a stressed material based primarily on its ability to generate an amount of lasting stress in adjacent layers without requiring any heating operation or oxidation after filling.

The stressed dielectric material may be filled into self-aligned diffusion break(s) 312 utilizing atomic layer deposition, plasma-enhanced atomic layer deposition, chemical vapor deposition, plasma-enhanced chemical vapor deposition, among other types of deposition methods. Nonetheless, in order to deposit the stressed dielectric material, the deposition of the stressed dielectric material may occur by utilizing increased RF power, higher deposition temperatures, higher kinetic energy plasma levels, or combinations thereof. Thus, in embodiments, the deposition process may occur with deposition temperatures of greater than or about 150° C., such as greater than or about 200° C., such as greater than or about 250° C., such as greater than or about 300° C., such as greater than or about 350° C., such as greater than or about 400° C., such as greater than or about 450° C., such as greater than or about 500° C., such as greater than or about 550° C., such as greater than or about 600° C., such as up to about 700° C., such as less than or about 650° C., or any ranges or values therebetween.

In embodiments, the stressed dielectric material may be characterized by a stress of greater than or about 500 MPa, such as greater than or about 1 GPa, such as greater than or about 1.5 GPa, such as greater than or about 2 GPa, such as greater than or about 2.25 GPa, such as greater than or about 2.5 GPa, such as greater than or about 2.75 GPa, such as greater than or about 3 GPa, or any ranges or values therebetween. For the purposes of this disclosure, a higher-stress material is characterized by an absolute value of stress, either positive or negative, that is greater than the absolute value of a lower-stress material. The convention used here is that positive stress is characterized as tensile stress, negative stress is characterized as compressive stress, and no stress (i.e., 0 GPa) is characterized as neutral stress. Positive (i.e., tensile) stress may characterized by an outward pushing force that may be created by the expansion of a material. Negative (i.e., compressive) stress may be characterized by an inward pulling force that may be created by the contraction of the material. Thus, a “compressive stressed” value as used herein may refer to a negative of the absolute value (e.g., a compressive stress of 250 MPa could also be read as −250 MPa), and a “tensile stressed” value as used herein may refer to a positive of the absolute value (e.g., a tensile stress of 250 MPa refers to 250 MPa).

Furthermore, in embodiments, the material may be deposited having thickness of about 1 nm or more, such as about 2.5 nm or more, such as about 5 nm or more, such as about 7.5 nm or more, such as about 10 nm or more, such as about 12.5 nm or more, such as about 15 nm or more, such as about 17.5 nm or more, such as about 20 nm or less, or any ranges or values therebetween. For instance, while it has been so far discussed that the self-aligned diffusion break(s) 312 may be filled with the stressed dielectric material, the present disclosure has found that the above stress levels and improved mobility may be achieved when the stressed dielectric material is utilized as a stress liner for self-aligned diffusion break 312. Thus, in some aspects, a thin liner of stressed dielectric material may partially or fully coat an interior surface of self-aligned diffusion break 312, and the remainder of the trench is then filled with an un-stressed material, a conductive material, or the like.

However, it should be understood that, in embodiments, the self-aligned diffusion break 312 is filled with a stressed dielectric material such that greater than or about 90 vol. % of the volume defined by the self-aligned diffusion break is occupied with a stressed dielectric material, such as greater than or about 92 vol. %, greater than or about 94 vol. %, greater than or about 96 vol. %, greater than or about 98 vol. %, greater than or about 99 vol. %, or more, or any ranges or values therebetween. In embodiments, the volume defined by the self-aligned diffusion break may be completely occupied with the stressed dielectric material and no void or seam may be present. Namely, the present technology has found that even small voids in the self-aligned diffusion break can result in dramatic decreases in channel stress. For instance, voids or seams characterized by a size of less than or about 3 nm or less, such as less than or about 2 nm, or less than about 1 nm may result in a decrease in average channel stress of greater than 60%.

Thus, in embodiments, to obtain the high vol. % and decrease voids and seams, the filling step 204 may include only forming a thin layer of the stressed dielectric material, etching back part of the filled material, and then filling another thin layer of the stressed dielectric material, repeating in a cyclic in-situ manner until the self-aligned diffusion break filling is complete. Such a process may be particularly useful in high aspect ratio diffusion breaks, as the cyclic process may avoid pinch off, and allow for lower volume of voids and seams, and higher occupied volume of the stressed dielectric material.

Nonetheless, as noted above, the present technology has found that even thin layers of the stressed dielectric material may be effective for imparting stress when utilized in the self-aligned diffusion break. Thus, the above thicknesses may represent the fully width of the self-aligned diffusion break. In such instances, the self-aligned diffusion break may define a channel length L, defined as the distance between the source and drain regions as illustrated in FIG. 4. Channel length L may be characterized by a length of less than or about 35 nm, such as less than or about 30 nm, less than or about 25 nm, less than or about 20 nm, or less, or any ranges or values therebetween. Self-aligned diffusion break may be considered to be characterized by a high aspect ratio due to the small channel length and large diffusion break depth. In addition, in embodiments, only single self-aligned diffusion breaks, and no double diffusion breaks, are utilized in structure 300 while still imparting the necessary stress, thus allowing reduced size while maintaining effectiveness.

Moreover, while the illustrated embodiments contain two single self-aligned diffusion breaks 312 on opposing sides of three gate regions 306 in FIGS. 3A-3E, and two single self-aligned diffusion breaks 312 on opposing sides of a single gate region 306 in FIG. 4, it should be understood that the self-aligned diffusion breaks may be placed with any number of gate regions 306 between a pair of diffusion breaks. For example, one gate region 306 may be disposed between a pair of diffusion breaks, such as two gate regions, three gate regions, such as four gate regions, such as 5 gate regions, such as 6 gate regions, such as 7 gate regions, or more, depending on the desired stress for the channel regions 316 in structure 300. For example the number of channel regions 304 disposed between opposing self-aligned diffusion breaks 312 may be selected to maintain a channel stress of greater than or about 350 MPA, such as greater than or about 400 MPa, greater than or about 450 MPa, greater than or about 500 MPa, greater than or about 550 MPa, such as greater than about 650 MPa, such as greater than or about 750 MPa, such as greater than about 850 MPa, such as greater than or about 1000 MPa, or more, or any ranges or values therebetween.

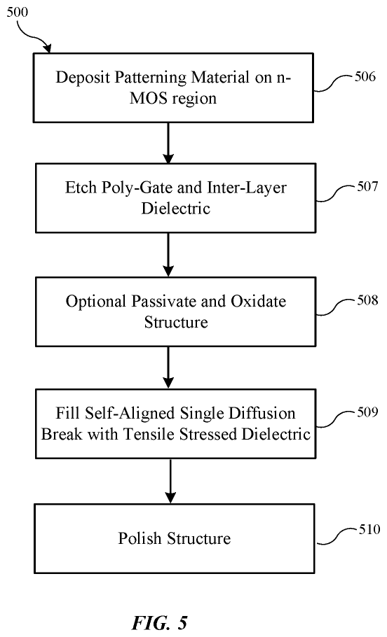

As noted above, in embodiments, the stress imparted by the stressed dielectric material may be a compressive stress, which may vastly improve mobility and drive current. However, in embodiments, the improvements noted above are specific to hole mobility and p-MOS drive-current. Thus, in one or more embodiments, the patterning discussed above is specific to single-diffusion break patterning in a p-MOS region. For instance, referring to FIG. 5, in embodiments where improvements in both p-MOS and n-MOS regions are necessary, a method 500 may include operations 506 to 510, where operation 506 occurs after operation 205 of FIG. 2. Namely, as shown, the method 500 may include a second patterning operation 506, which is conducted in the same manner as step 201, except that the patterning material is disposed over a n-MOS region. In such an embodiment, the substrate 302 may be transferred from process chamber 120 back to process chamber 114 for a second patterning step. Then, the substrate may be transferred from process chamber 114 to etch chamber 116 at operation 507 etching may occur. After the second etch process 507, an optional passivation/oxidation step may occur at operation 508, followed by transfer to process chamber 118 for stressed dielectric fill at operation 508, which may occur in the same or similar manner as etching and filling operations 202 and 203, utilizing second patterning operation 506. Of course, it should be understood that, in embodiments, method operations 506 to 510 may occur wholly, or in part, before steps 201 to 205. Nonetheless, after a second deposition fill operation 509, the substrate 302 may be transferred back to process chamber 120 for a second polishing operation 510.

In addition, a stressed dielectric material as discussed above may still be utilized to fill the formed self-aligned diffusion break 312. However, in order to facilitate further improvement in a n-MOS region, a tensile stressed dielectric material may be utilized (or tensile stress may be induced in the stressed dielectric material). For instance, high oxygen deposition environments, or UV curing may be utilized, as examples only. Nonetheless, the present technology has found that the deposition of a tensile stressed dielectric material in a single self-aligned diffusion break in a n-MOS region can further improve electron mobility and n-MOS current drive without detrimentally effecting the hole mobility and p-MOS current drive properties discussed above.

Thus, in addition to the improvements discussed above, the increased stress in the channel region is thought to increase the mobility of charge carriers in the channel, which increases the drive current through the n-MOS channel region. In embodiments, the increased stress created in the channel region by embodiments of the present technology may increase the drive current through a transistor channel by greater than or about 1%, such as greater than or about 5%, greater than or about 10%, greater than or about 15%, greater than or about 20%, greater than or about 25%, greater than or about 30%, greater than or about 35%, greater than or about 40%, greater than or about 45%, greater than or about 50%, greater than or about 55%, or greater, or any ranges or values therebetween. An increase in drive current and hole mobility through the channel region may increase transistor performance in a number of respects including, but not limited to, increased switching speed and/or reduced power consumption.

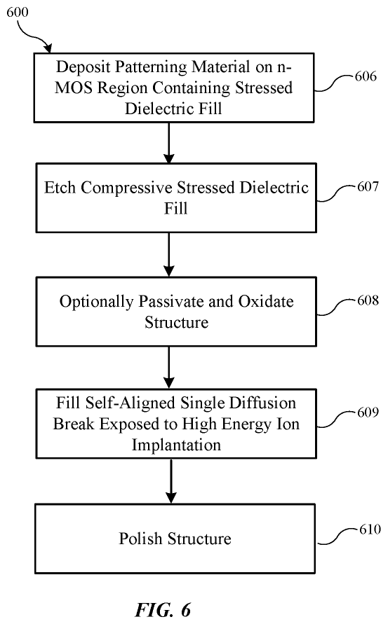

An alternative method to improve electron mobility and n-MOS current drive is shown in the method 600 of FIG. 6. Namely, operations 201 to 205 may occur in the same manner as method 200. After operation 205, the method may include transferring the substrate back to process chamber 114 for an operation 606 to deposit a second patterning mask. After the mask is deposited, the substrate may be transferred to process chamber 116 at operation 607 to etch the second patterning mask to expose a self-aligned diffusion break 312 in a n-MOS region. The self-aligned diffusion break is etched at operation 607 according to any of the methods discussed above. However, the etching here removes the stressed dielectric fill from the self-aligned diffusion break in the n-MOS region. The structure 300 is then subjected to an optional passivation/oxidation operation at 608. Nonetheless, the substrate 302 is transferred to fill/deposition chamber 118, where the etched diffusion break is exposed to a high energy ion implantation at operation 609 that relaxes the compressive stress previously introduced into the diffusion break. Suitable high energy implantations can include silicon, germanium, xenon, indium, or the like. Nonetheless, as discussed above, the high energy implantation may render a similar decrease in stress in the n-MOS region as the tensile stressed dielectric fill, such as back to a first stress value, improving electron mobility and n-MOS drive-current without impacting the improvements in hole mobility and p-MOS drive current imparted by the compressive stressed dielectric fill. Finally, the substrate 302 may be transferred to process chamber 120, where the substrate may undergo polishing at operation 610.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a gate region” includes a plurality of such regions, and reference to “the gate region” includes reference to one or more gate regions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor device, comprising:
a substrate;
a source region;
a drain region;
a channel region comprising at least one channel located between the source and the drain;
a first gate region comprising a self-aligned single diffusion break in a p-MOS region, wherein the self-aligned single diffusion break comprises a stressed dielectric material, and wherein the stressed dielectric material is characterized by a compressive stress of greater than or about 500 MPa; and
a second gate region in an n-MOS region comprising a first gate enclosing the channel between the source region and the drain region.

2. The semiconductor device of claim 1, wherein the channel region is characterized by a compressive stress of greater than or about 500 MPa.

3. The semiconductor device of claim 1, further comprising a third gate region, wherein the second gate region is disposed between the first gate region and the third gate region.

4. The semiconductor device of claim 3, wherein the third gate region comprises a second self-aligned single diffusion break in a p-MOS region.

5. The semiconductor device of claim 3, wherein the channel region has a first channel region stress at a first location and a second channel region stress at a second location spaced apart from the first location within the channel region, wherein the first channel region stress relative to the second channel region stress is characterized by a percentage change of greater than or about 30%.

6. The semiconductor device of claim 5, wherein the channel region comprises a plurality of horizontally extending channels.

7. The semiconductor device of claim 5, wherein the semiconductor device is a gate-all-around complementary metal-oxide-semiconductor.

8. The semiconductor device of claim 4, wherein the second self-aligned single diffusion break comprises a tensile stressed dielectric material characterized by a tensile stress of greater than or about 500 MPa.

9. The semiconductor device of claim 4, wherein the third gate region comprises a third self-aligned diffusion break, the third self-aligned diffusion break comprising a compressive stressed dielectric material characterized by a compressive stress of greater than or about 500 MPa.

10. The semiconductor device of claim 8, wherein the second self-aligned single diffusion break comprises a tensile stressed dielectric material or a high energy implantation.

11. The semiconductor device of claim 1, wherein the self-aligned diffusion break defines a volume, and wherein the stressed dielectric material occupies about 90 vol. % or more of the volume.

12. The semiconductor device of claim 11, wherein the stressed dielectric material is generally free of voids or seams.

13. The semiconductor device of claim 12, wherein the stressed dielectric material occupies greater than or about 98 vol % of the volume.

14. The semiconductor device of claim 1, wherein the stressed dielectric material has a compressive stress of greater than or about 1000 MPa, the channel region is a p-channel metal oxide semiconductor, and the channel region has a compressive stress of greater than or about 600 MPa.

15. A semiconductor processing system, comprising:
a first processing chamber;
a second processing chamber;
a third processing chamber; and
a system controller configured to pattern a substrate in the first processing chamber,
etch a shallow trench isolation in a first gate region of a semiconductor device, wherein the first gate region is a p-MOS region, in the second processing chamber,
fill the shallow trench isolation with a stressed dielectric material having a compressive stress of at least about 500 MPa in the third processing chamber.

16. A method of forming a semiconductor device, comprising:
etching a shallow trench isolation in a first gate region of a semiconductor device, wherein the first gate region is a p-MOS region, wherein the semiconductor device contains a substrate, a source region, a drain region, a channel region containing at least one channel located between the source and the drain, the first gate region, and a second gate region in a n-MOS region comprising a first gate enclosing the channel between the source region and the drain region; and
filling the shallow trench isolation with a compressive stressed dielectric material having a stress of at least about 500 MPa.

17. The method of claim 16, wherein the channel region, prior to etching, is characterized by a first stress, wherein the channel region, subsequent the filling, is characterized by a second stress, and wherein the first stress relative to the second stress is characterized by a percentage change of greater than or about 10% or wherein the channel region, prior to etching, is characterized by a first hole mobility, and subsequent the filling, is characterized by a second hole mobility, and wherein the first hole mobility relative to the second hole mobility is characterized by a percentage change or greater than or about 10%.

18. The method of claim 16, further comprising a third gate region, the second gate region being disposed between the first gate region and the third gate region.

19. The method of claim 18, further comprising etching the third gate region etched during the etching of the first gate region, or masking the third gate region during the etching of the first gate region and patterning and etching the third gate region after etching the first gate region, forming a second shallow trench isolation in the third gate region.

20. The method of claim 19, further comprising filling the shallow trench isolation with a compressive stressed dielectric material and filling the second shallow trench isolation with a compressive stressed dielectric material, a tensile stressed dielectric material, or a high energy implantation.
